(19) United States
(12) Patent Application Publication
(10) Pub. No.: US 2012/0119346 A1
(43) Pub. Date: May 17, 2012

(54) SEMICONDUCTOR PACKAGE AND METHOD OF FORMING THE SAME

(76) Inventors: YUNHYEOK IM, Yongin-si (KR); Chungsun Lee, Gunpo-si (KR); Taeje Cho, Hwaseong-si (KR)

(21) Appl. No.: 13/243,996

(22) Filed: Sep. 23, 2011

(30) Foreign Application Priority Data
Nov. 17, 2010 (KR) 10-2010-0114550

(51) Int. Cl. H01L 23/02; H01L 23/48

(52) U.S. Cl. 257/690; 257/E23.18; 257/E23.011

(57) ABSTRACT

Disclosed are a semiconductor package and a method of manufacturing the same. The semiconductor package comprises a package cap which is capable of radiating high temperatures and performs a shield function preventing transmission of electromagnetic waves into and/or out of the semiconductor package. The semiconductor package including the package cap prevents chip malfunctions and improves device reliability. The package cap is positioned to cover first and second semiconductor chips of a semiconductor package.

### CROSS-REFERENCE TO RELATED APPLICATIONS

This application claims priority, under 35 U.S.C § 119, from Korean Patent Application No. 10-2010-0114550 filed Nov. 17, 2010, the entirety of which is incorporated by reference herein.

### BACKGROUND

1. Field

Exemplary embodiments relate to a semiconductor package and a method of fabricating the semiconductor package.

2. Discussion of the Related Art

With trends toward small, slim and dense electronic products, small and slim printed circuit boards are required. Together with portability of electronic devices, multi-function and mass data transmitting and receiving functions may necessitate complicated printed circuit board designs. As a result, there has been an increased need for multi-layer printed circuit boards where power supply circuits, ground circuits, signal circuits, etc. are formed.

Semiconductor chips, such as central processing units, power integrated circuits, and the like may be mounted on multi-layer printed circuit boards. Such semiconductor chips may generate high temperature when in use. The high temperature may cause malfunctions of the semiconductor chips due to overload.

When a plurality of semiconductor chips are mounted on a printed circuit board, electromagnetic interference (EMI) may be generated between the semiconductor chips. Such EMI may cause malfunctions of the semiconductor chips.

### SUMMARY

According to an embodiment of the inventive concept , a semiconductor package comprises a package substrate including a package cap interconnection through via at opposite edges of the package substrate, a first semiconductor chip stacked on the package substrate, at least one second semiconductor chip stacked on the first semiconductor chip and having a width narrower than a width of the first semiconductor chip, a molding film covering an upper surface of the first semiconductor chip adjacent to a lateral surface of the second semiconductor chip, and covering a lateral surface of the second semiconductor chip, a thermal interface film disposed on the second semiconductor chip, a package cap in contact with the thermal interface material film and covering the first and second semiconductor chips, and a package adhesion pattern between the package cap interconnection through via and a lower part of the package cap.

In an exemplary embodiment, an upper surface of the molding film is positioned at the same height as an upper surface of the second semiconductor chip and the thermal interface film is extended from on top of the second semiconductor chip to on top of the molding film, and is between the molding film and the package cap.

In another exemplary embodiment, an upper surface of the molding film is higher than an upper surface of the second semiconductor chip.

The package substrate further comprises a package ground layer, the package cap interconnection through via being in contact with the package ground layer. Alternatively, the package cap interconnection through via is not in contact with the package ground layer.

The package cap interconnection through via is formed of a conductive film. Alternatively, the package cap interconnection through via is formed of an insulation film.

The package adhesion pattern is conductive.

The package cap includes a portion (e.g., a pin portion) protruding upward from the package cap.

In an exemplary embodiment, the package substrate further comprises conductive layers and a plurality of insulation films being stacked in a multi-layer structure, and the package cap interconnection through via includes a plurality of sub through vias penetrating the insulation films and disposed at different layers from each other. In this case, adjacent sub through vias in the vertical direction are not aligned with (i.e., offset from) each other.

The package substrate further comprises a power layer, the package cap interconnection through via not being with the power layer.

The molding film is formed of thermal epoxy.

The thermal interface film is formed of thermal grease, epoxy material, or metallic solid particles included in an epoxy material.

According to embodiments of the inventive concept, a method of manufacturing a semiconductor package comprises preparing a wafer including a plurality of first semiconductor chips, mounting a plurality of second semiconductor chips on the wafer including the plurality of first semiconductor chips, each of the plurality of second semiconductor chips respectively overlapping a first semiconductor chip of the plurality of first semiconductor chips, forming a molding film covering the second semiconductor chips, removing part of the molding film to expose upper surfaces of the second semiconductor chips, separating the wafer into unit portions having a second semiconductor chip stacked on a first semiconductor chip, mounting the first semiconductor chip of a unit portion on a package substrate, and covering the first and second semiconductor chips of the unit portion with a package cap, wherein a thermal interface film is positioned between the package cap and the second semiconductor chip of the unit portion.

The covering the first and second semiconductor chips by the package cap includes fixing the package cap with an adhesion pattern positioned between the package cap and the package substrate.

The forming a molding film covering a lateral surface of the second semiconductor chip an exposing an upper surface of the second semiconductor chip includes forming a molding film covering lateral and upper surfaces of the second semiconductor chip, and exposing the upper surface of the second semiconductor chip by grinding the molding film.

The method further comprises forming the thermal interface material film before separating the wafer.

According to an embodiment of the inventive concept, a semiconductor package comprises a package substrate including a through via, a first semiconductor chip stacked on the package substrate, at least one second semiconductor chip stacked on the first semiconductor chip and having a width narrower than a width of the first semiconductor chip, a molding film on a portion of an upper surface of the first semiconductor chip adjacent to a lateral surface of the second semiconductor chip, a thermal interface film disposed on the second semiconductor chip, a package cap in contact with the thermal interface film and positioned over the first and second semiconductor chips, and a conductive package adhesion pattern between the through via and a part of the package cap.

### BRIEF DESCRIPTION OF THE FIGURES

Embodiments of the present inventive concept will become apparent from the following description with reference to the following figures, wherein like reference numerals may refer to like parts throughout the various figure, and wherein

FIG. 1 is a cross-sectional view of a semiconductor package according to an embodiment of the inventive concept.

FIG. 2 is a diagram for describing heat transmission in the semiconductor package of FIG. 1.

FIG. 3 is a diagram showing voltages applied to the semiconductor package of FIG. 1.

FIGS. 4 to 13 are cross-sectional views for describing a method of manufacturing a semiconductor package, according to an embodiment of the inventive concept.

FIG. 14 is a cross-sectional view of a semiconductor package according to an embodiment of the inventive concept.

FIG. 15 is a cross-sectional view of a semiconductor package according to an embodiment of the inventive concept.

FIG. 16 is a cross-sectional view of a semiconductor package according to an embodiment of the inventive concept.

FIG. 17 is a cross-sectional view of a semiconductor package according to an embodiment of the inventive concept.

FIG. 18 is a cross-sectional view of a semiconductor package according to an embodiment of the inventive concept.

FIG. 19 is a cross-sectional view of a semiconductor package according to an embodiment of the inventive concept.

FIG. 20 is a cross-sectional view of a semiconductor package according to an embodiment of the inventive concept.

FIG. 21 is a diagram showing heat transmission in the semiconductor package of FIG. 20.

FIG. 22 is a block diagram showing a semiconductor module according to an embodiment of the inventive concept.

FIG. 23 is a block diagram showing a semiconductor module according to an embodiment of the inventive concept.

FIG. 24 is a block diagram showing a semiconductor module according to an embodiment of the inventive concept.

FIG. 25 is a block diagram showing an electronic device including a semiconductor package according to exemplary embodiments of the inventive concept.

### DETAILED DESCRIPTION

The inventive concept is described more fully hereinafter with reference to the accompanying drawings, in which embodiments of the inventive concept are shown. This inventive concept may, however, be embodied in many different forms and should not be construed as limited to the embodiments set forth herein. In the drawings, the size and relative sizes of layers and regions may be exaggerated for clarity. Like numbers may refer to like elements throughout.

As used herein, the term “and/or” includes any and all combinations of one or more of the associated listed items.

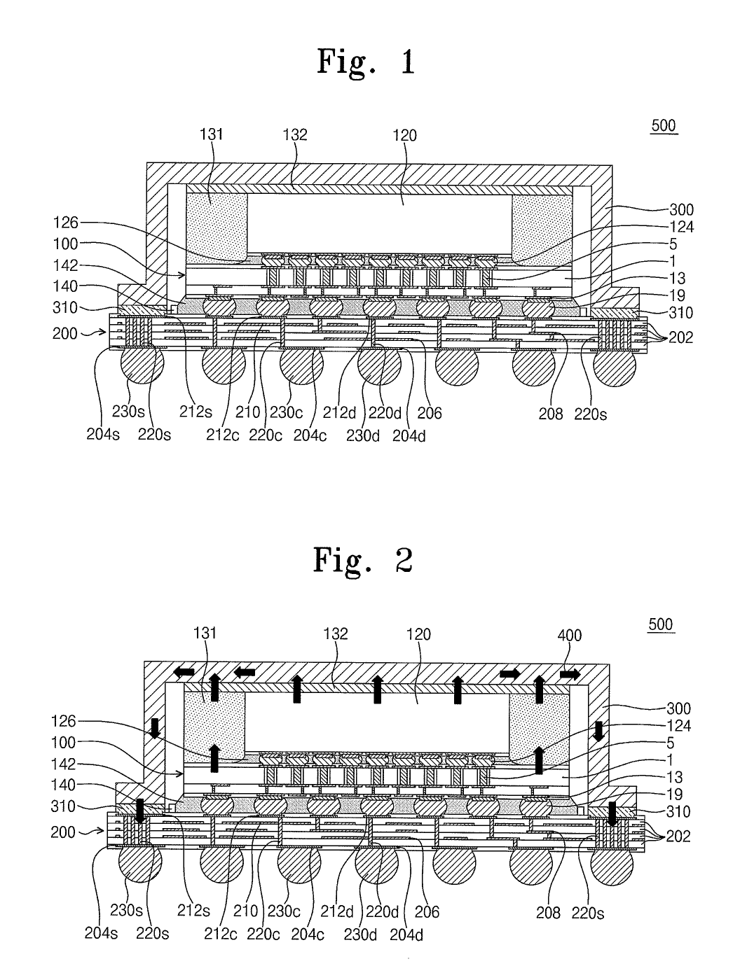

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. FIG. 1 is a cross-sectional view of a semiconductor package according to an embodiment of the inventive concept.

Referring to FIG. 1, a semiconductor package 500 includes a first semiconductor chip 100 and a second semiconductor chip 120 mounted on a package substrate 200. A package cap 300 is formed on the package substrate 200 and covers the first and second semiconductor chips 100 and 120.

According to an embodiment, the package substrate 200 is a multi-layer printed circuit board. The package substrate 200 includes a plurality of insulation films 202. First signal patterns 204s, 204c, and 204d are disposed on an insulation film placed at the lowermost layer among the insulation films 202. According to an embodiment, the first signal patterns 204s, 204c, and 204d include a first package cap interconnection signal pattern 204s, a first chip ground voltage signal pattern 204c, and a first power supply voltage signal pattern 204d. Second signal patterns 212s, 212c, and 212d are disposed on an insulation film placed at the uppermost layer among the insulation films 202. The second signal patterns 212s, 212c, and 212d include a second package cap interconnection signal pattern 212s, a second chip ground voltage signal pattern 212c, and a second power supply voltage signal pattern 212d. According to an embodiment, a package power layer 206 and a package ground layer 210 are disposed in insulation films 202 located at different layers from each other. Third signal patterns 208 are also disposed in one or more insulation films 202. The first signal patterns 204s, 204c, and 204d, the second signal patterns 212s, 212c, and 212d, the package power layer 206, the third signal patterns 208, and the package ground layer 210 are formed of a conductive film. The package substrate 200 includes a plurality of package substrate through vias 220s, 220c, and 220d which penetrate the insulation films 202. The package substrate through vias 220s, 220c, and 220d include a package cap interconnection through via 220s, a chip ground voltage through via 220c, and a power supply voltage through via 220d. The package cap interconnection through via 220s is disposed adjacent to an edge of the package substrate 200.

The package cap interconnection through via 220s connects the first package cap interconnection signal pattern 204s and the second package cap interconnection signal pattern 212s without being connected to the package power layer 206 and the package ground layer 210. The chip ground voltage through via 220c connects the first chip ground voltage signal pattern 204c and the second chip ground voltage signal pattern 212c and is connected with the package ground layer 210. The power supply voltage through via 220d connects the first power supply voltage signal pattern 204d and the second power supply voltage signal pattern 212d and is connected to the package power layer 206.

Outer solder balls 230s, 230c, and 230d are attached at lower parts of the first signal patterns 204s, 204c, and 204d, respectively. The outer solder balls 230s, 230c, and 230d include a package cap interconnection outer solder ball 230s, a chip ground voltage outer solder ball 230c, and a power supply voltage outer solder ball 230d.

A width of the second semiconductor chip 120 is less than that of the first semiconductor chip 100. For example, according to an embodiment, the first semiconductor chip 100 is a logic chip, and the second semiconductor chip 120 is a memory chip. The first semiconductor chip 100 includes a semiconductor substrate 1, a chip through via 5 penetrating the semiconductor substrate 1, and a chip ball land 13 electrically connected with the chip through via 5. According to an embodiment, the first semiconductor chip 100 is mounted on the package substrate 200 in a flip chip bonding manner. The second semiconductor chip 120 is mounted on the first semiconductor chip 100 in the flip chip bonding manner. The chip ball land 13 of the first semiconductor chip 100 is electrically connected with the second signal patterns 212c and 212d by first inner solder balls 19. The first and second semiconductor chips 100 and 120 are electrically connected to each other by second inner solder balls 124. A dam 140 is disposed adjacent to an edge of the package substrate 200. A space between and around the second inner solder balls 124 is filled by a first underfill resin film 126. A space between and around the first inner solder balls 19 is filled by a second underfill resin film 142.

A molding film 131 is positioned to cover part of an upper surface of the first semiconductor chip 100 and a lateral surface of the second semiconductor chip 120. According to an embodiment, the upper surface of the second semiconductor chip 120 may be level in height with the upper surface of the molding film 131. The molding film 131 is formed of, for example, an epoxy resin series.

In an exemplary embodiment, a thermal interface film 132 is interposed between the package cap 300 and the second semiconductor chip 120 and between the package cap 300 and the molding film 131. The thermal interface film 132 includes, for example, thermal grease, epoxy material, or metallic solid particles such as indium mixed with the thermal grease and epoxy material. The thermal interface film 132 maintains a solid state at a low temperature and is changed into a liquid state at a high temperature. According to an embodiment, the thermal interface film 132 has an adhesive function and/or is conductive.

According to an embodiment, the package cap 300 is formed of a metallic material. A package adhesion pattern 310 is positioned between a lower part of the package cap 300 and an edge of the package substrate 200. The package adhesion pattern 310 is used to adhere and fix the package cap 300 to the package substrate 200. In an exemplary embodiment, the package adhesion pattern 310 is conductive. According to an embodiment, the package adhesion pattern 310 is adjacent to the second package cap interconnection signal pattern 212s. Further, according to an embodiment, the package adhesion pattern 310 overlaps the package cap interconnection through vias 220s. According to an embodiment, since the package cap 300 is fixed to the package substrate 200 and the package adhesion pattern 310 positioned on the package substrate 200 is connected thermally and electrically to the package substrate 200, it is not necessary to form holes for shield cans or thermal sink plates at a package substrate, a module substrate, or a mother board. Accordingly, not required to alter the designs for package, module, or mother substrates by forming the holes.

FIG. 2 is a diagram for describing heat transmission in the semiconductor package of FIG. 1.

Referring to FIG. 2, heat produced by first and second semiconductor chips 100 and 120 flows according to an arrow direction 400. The heat produced by the second semiconductor chip 120 is transmitted through a thermal interface material film 132 to a package cap 300 having high thermal conductivity, and the heat in the package cap 300 is spreads out over the area of the package cap 300 prior to being transmitted to a second package cap interconnection signal pattern 212s, a package cap interconnection through via 220s, and a first package cap interconnection signal pattern 204s. The heat produced by the first semiconductor chip 100, being the lowermost one of the semiconductor chips 100 and 120, spreads through the second semiconductor chip 120 and is transmitted to the package cap 300 through the second semiconductor chip 120, the molding film 131 and the thermal interface film 132. The package cap 300 functions as a heat spreader or a heat sink which discharges the heat from the first and second semiconductor chips 100 and 120. Accordingly, since the package cap 300 discharges produced heat, it is possible to prevent malfunctions of the semiconductor chips 100 and 120 due to high temperature. As a result, the reliability of the semiconductor package 500 is improved.

According to an embodiment, the molding film 131 is formed of an epoxy series material, which has the thermal conductivity of about 0.30 W/(m·K) to about 7 W/(m·K). For example, in the case that the molding film 131 is formed of a thermal epoxy, its thermal conductivity is about 1 W/(m·K) to about 7 W/(m·K), which is higher than 0.025 W/(m·K) the thermal conductivity of air. Accordingly, if the molding film 131 is located between the thermal interface material film 132 and the first semiconductor chip 100, it is possible to discharge the heat more effectively as compared to the situation when air instead of the molding film 131 is located between the thermal interface material film 132 and the first semiconductor chip 100. That is, it is possible to increase the discharge of heat produced by the first semiconductor chip 100 by positioning the molding film 131 between the thermal interface material film 132 and the first semiconductor chip 100. In a case where the molding film 131 is formed of thermal epoxy, for example, a heat spreading or heat sinking effect may be improved.

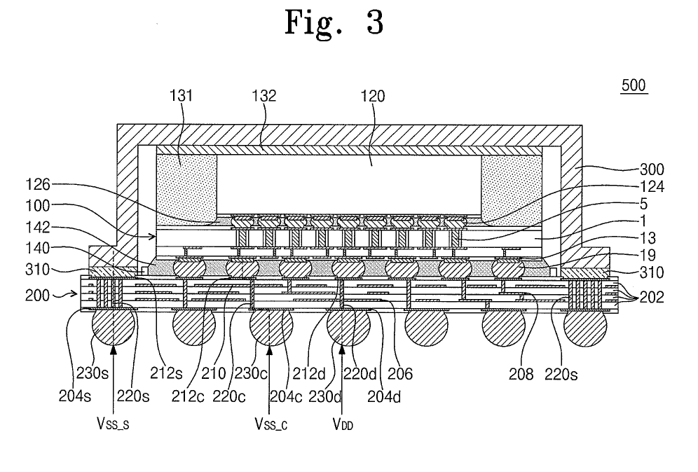

FIG. 3 is a diagram showing voltages applied to a semiconductor package of FIG. 1.

Referring to FIG. 3, a cap ground voltage V_{SS}_{_{—}}_{S} is applied to a package cap interconnection outer solder ball 230s. The cap ground voltage V_{SS}_{—s} is applied to the package cap 300 from an external source through the package cap interconnection outer solder ball 230s, a first package cap interconnection signal pattern 204s, a package cap interconnection through via 220s, a second package cap interconnection signal pattern 212s, and a package adhesion pattern 310. The cap ground voltage V_{SS}_{_{—}}_{S} is a ground voltage. A chip ground voltage V_{SS}_{_{—}}_{C} is applied to a chip ground voltage outer solder ball 230c. The chip ground voltage VSS_C is applied to a first semiconductor chip 100 from an external source through a chip ground voltage outer solder ball 230c, a first chip ground voltage signal pattern 204c, a chip ground voltage through via 220c, and a second chip ground voltage signal pattern 212c. A power supply voltage V_{DD} is applied to a power supply voltage outer solder ball 230d. The power supply voltage V_{DD} is supplied to the first semiconductor chip 100 from an external source through a power supply voltage outer solder ball 230d, a first power supply voltage signal pattern 204d, a power supply voltage through via 220d, and a second power supply voltage signal pattern 212d. Since the package cap 300 is grounded through a path different from the semiconductor chips 100 and 120, the electrostatic discharge (ESD) noise is more effectively reduced.

As illustrated in FIG. 3, the first and second semiconductor chips 100 and 120 are supplied with the same chip ground voltage V_{SS}_{_{—}}_{C} and the power supply voltage V_{DD}. In some embodiments, the first and second semiconductor chips 100 and 120 are formed to receive different chip ground voltages V_{SS}_{_{—}}_{C} and power supply voltages V_{DD}. For example, the chip ground voltage V_{SS}_{_{—}}_{C} and the power supply voltage V_{DD} supplied to the first semiconductor chip 100 through a first path are different from the chip ground voltage V_{SS}_{_{—}}_{C} and the power supply voltage V_{DD} supplied to the second semiconductor chip 120 through a second path different from the first path.

In some embodiments, the package cap interconnection through via 220s is formed of an insulation film. According to the present embodiment, the package cap 300 performs a heat spreading function.

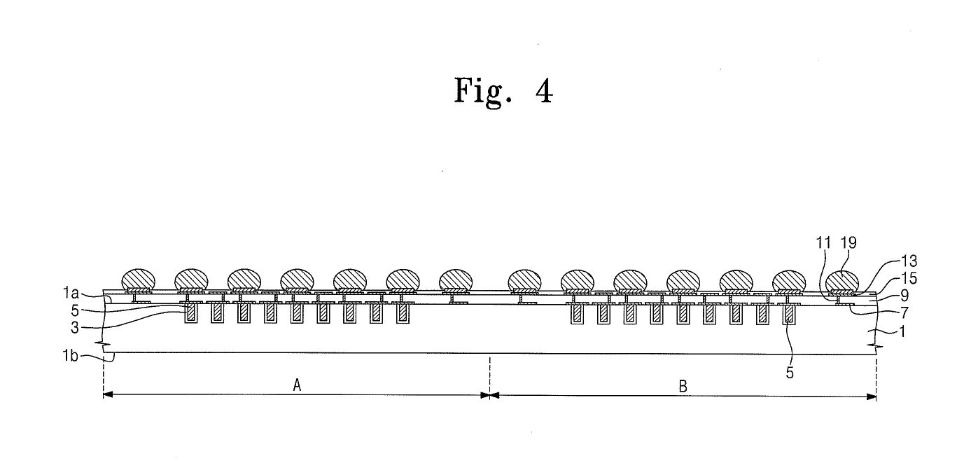

FIGS. 4 to 13 are cross-sectional views for describing a method of manufacturing a semiconductor package in accordance with an embodiment of the present invention.

Referring to FIG. 4, a process of making a first semiconductor chip 100 is described. A plurality of chip through vias 5 are formed in a semiconductor substrate (or, a wafer) 1 which includes a first surface 1a and a second surface 1b, and a plurality of chip regions A and B. The first surface 1a is positioned opposite to the second surface 1b. Barrier films 3 are formed between the chip through vias 5 and the semiconductor substrate 1. A plurality of conductive patterns 7 and 11 are formed on the first surface 1a of the semiconductor substrate 1 and are electrically connected with an interlayer insulation film 9 and the chip through vias 5. A first chip ball land 13 and a first chip passivation film 15 including an opening partially exposing the first chip ball land 13 are formed on the interlayer insulation film 9. A first inner solder ball 19 is attached to the chip ball land 13.

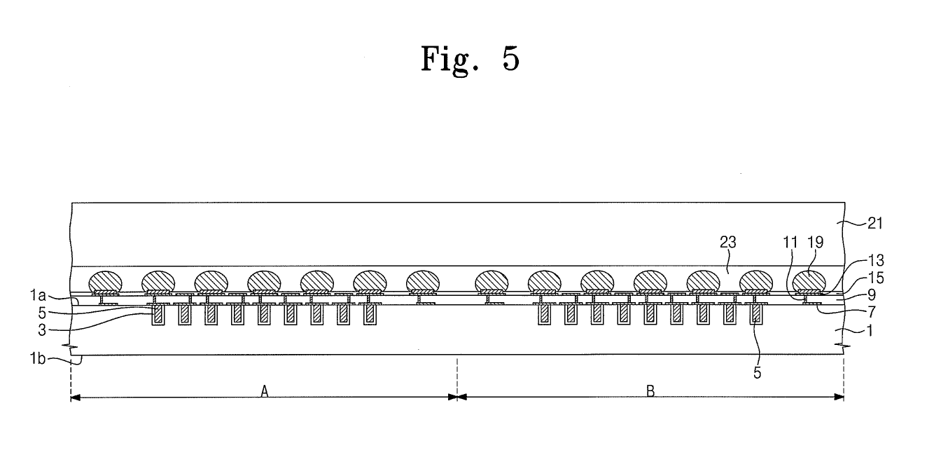

Referring to FIG. 5, a carrier substrate 21 is attached on the first surface 1a of the semiconductor substrate 1 with an adhesive film 23 being interposed between the first surface 1a and the carrier substrate 21.

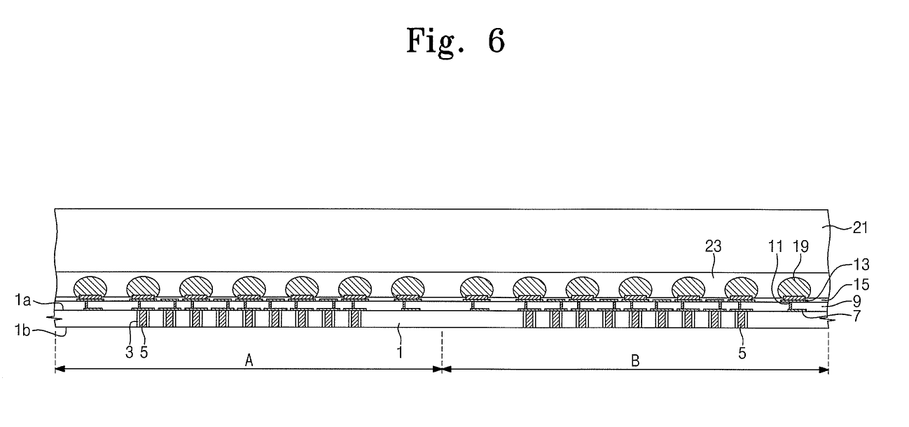

Referring to FIG. 6, lower surfaces of the chip through vias 5 are exposed by polishing the semiconductor substrate 1 adjacent to the second surface 1b to remove part of the semiconductor substrate from the second surface 1b.

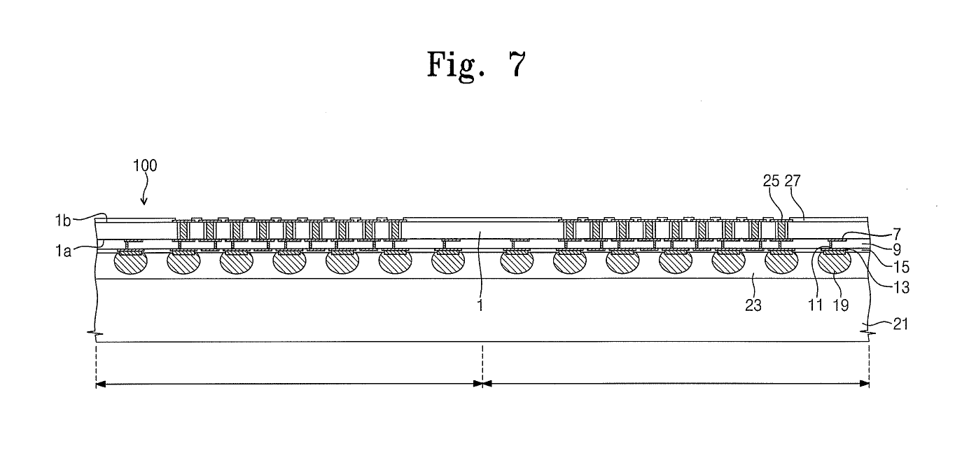

Referring to FIG. 7, the semiconductor substrate 1 is turned over such that the second substrate 1b is placed upwards. A second chip ball land 25 and a second chip passivation film 27 are formed on the second surface 1b of the semiconductor substrate 1 by performing a re-wiring process. The resulting structure includes first semiconductor chips 100 electrically connected one another before separating the semiconductor chips 100 into unit chips.

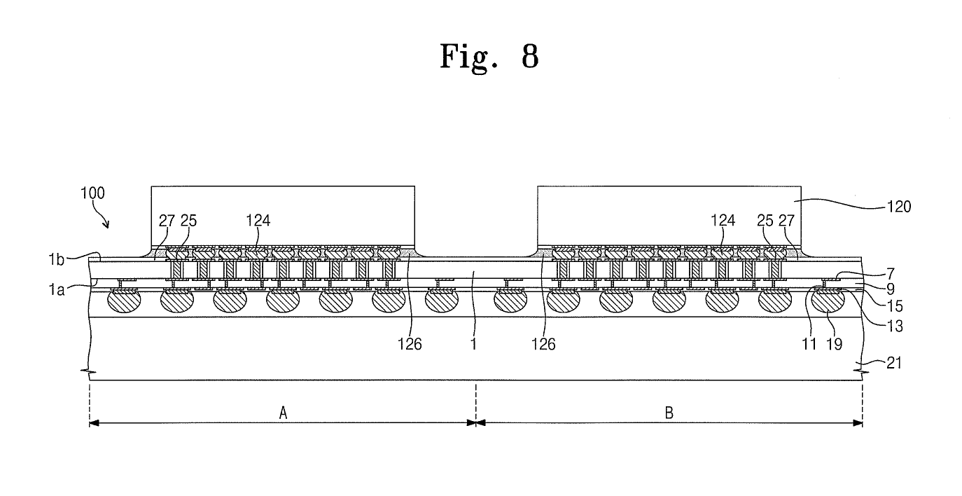

Referring to FIG. 8, second semiconductor chips 120 are mounted on the unit chip regions A and B, respectively. According to an embodiment, the second semiconductor chip 120 is mounted in a flip chip bonding manner on the first semiconductor chip 100, where the second inner solder ball 124 is positioned between the first and second semiconductor chips 100, 120. A first underfill resin film 126 is formed to fill a space between and around the second inner solder balls 124.

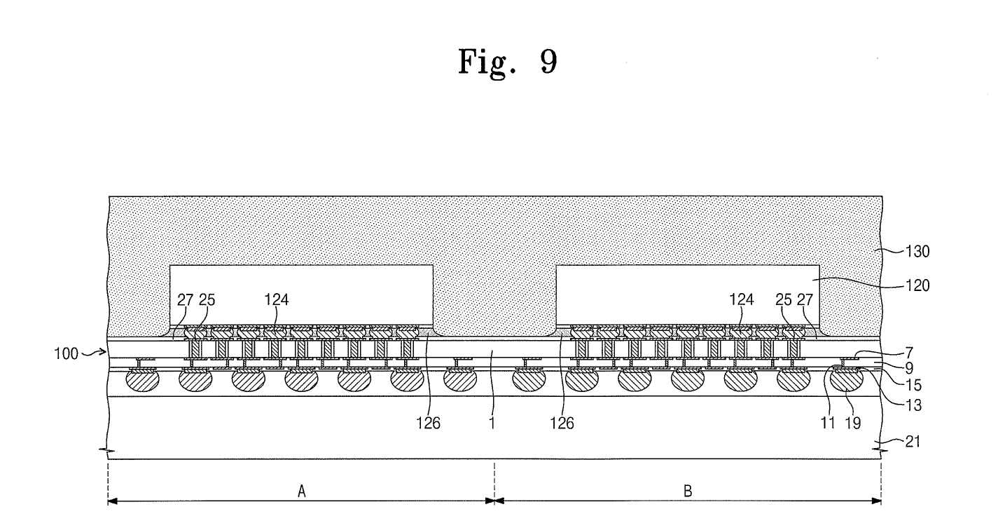

Referring to FIG. 9, a mold film 130 is formed on the first semiconductor chip 100 through a molding process. The molding film 130 covers an upper surface of the second semiconductor chips 120.

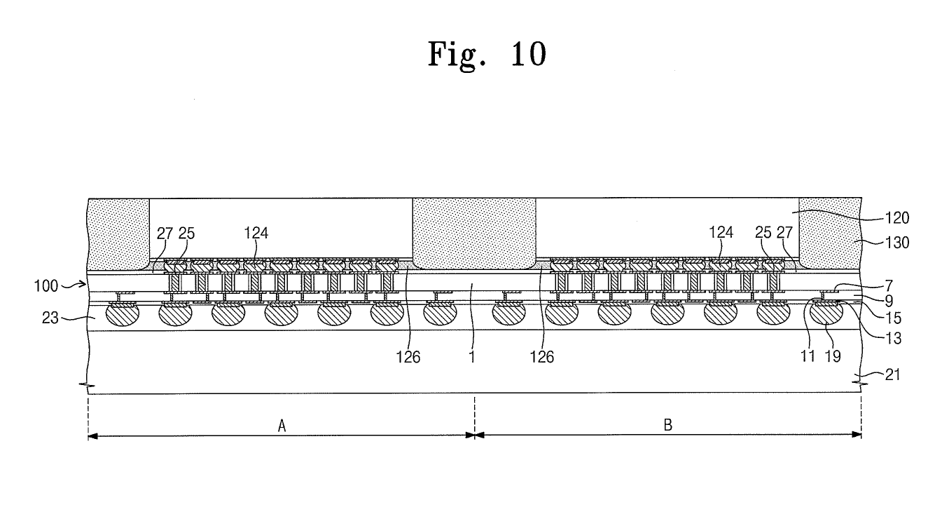

Referring to FIG. 10, the molding film 130 is ground to expose upper surfaces of the second semiconductor chips 120.

In an exemplary embodiment, the molding film 130 covers lateral sides of the second semiconductor chips 120 and the upper surfaces of the second semiconductor chips 120 are exposed.

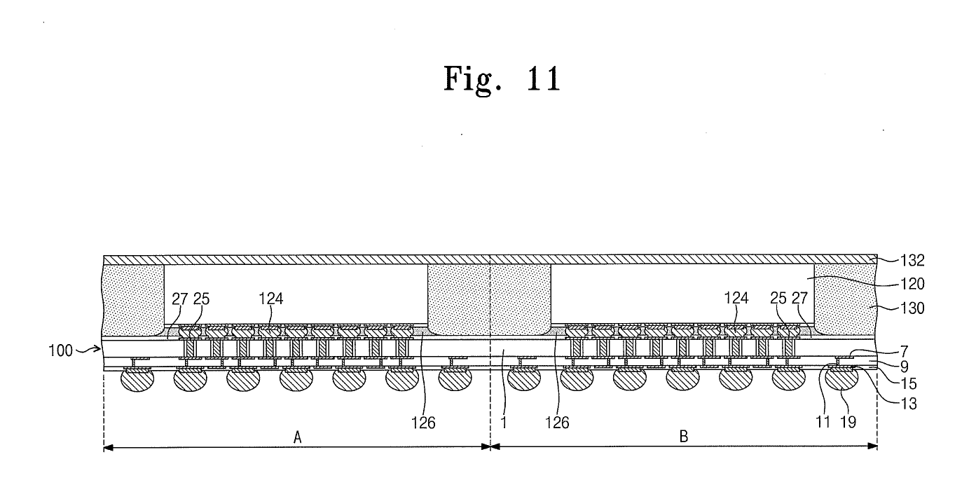

Referring to FIG. 11, a thermal interface film 132 is formed to cover the upper surfaces of the second semiconductor chips 120 and an upper surface of the molding film 130. According to an embodiment, the thermal interface film 132 is formed using a paste, inkjet printing or spin coating process. The first inner solder balls 19 are exposed by removing the carrier substrate 21 and the adhesive film 23.

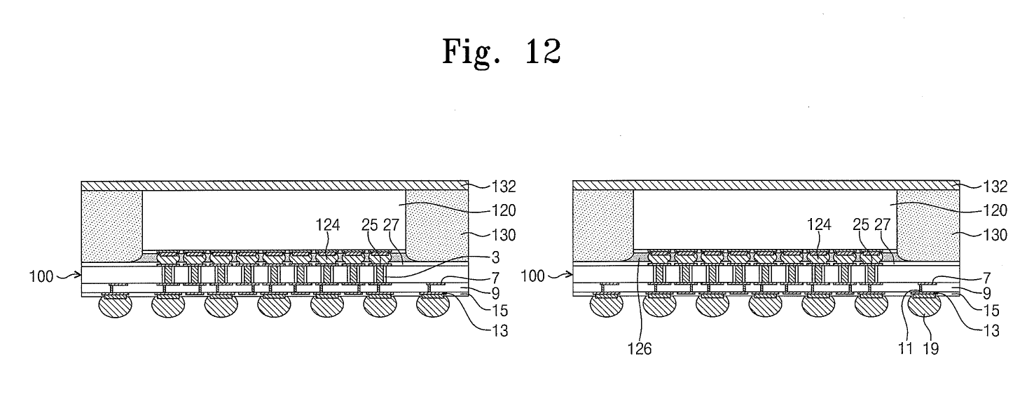

Referring to FIG. 12, a cutting process is performed to cut the wafer 1, which includes the first semiconductor chips 100 having the second semiconductor chips 120 embedded therein, into unit chips.

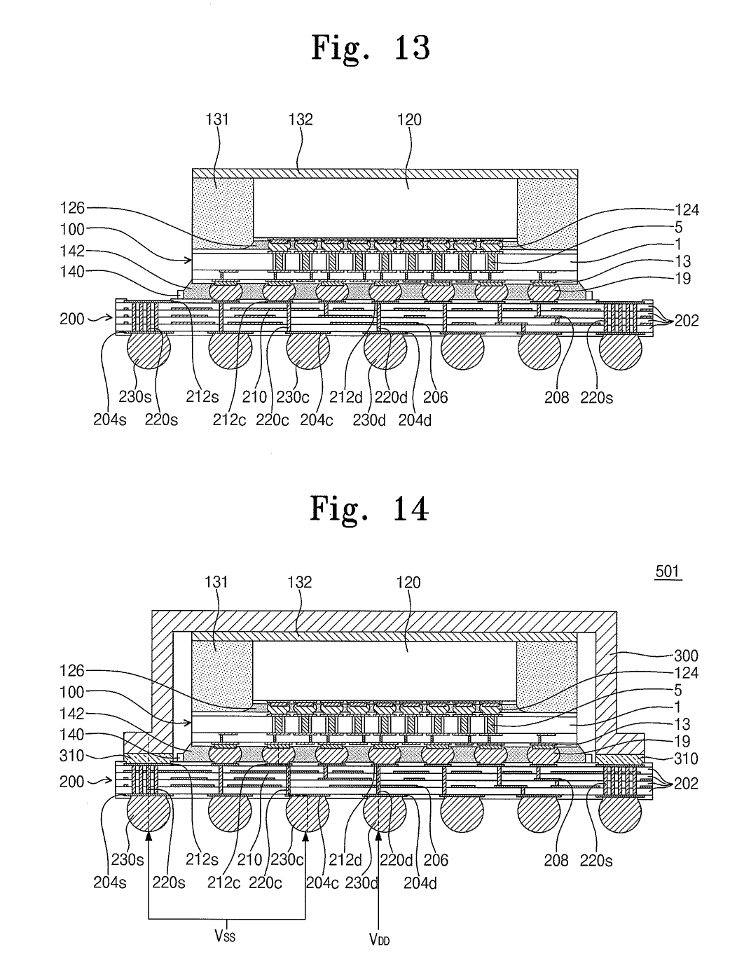

Referring to FIG. 13, a package substrate 200 is prepared. The package substrate 200 is formed of a multi-layer printed circuit board and includes a plurality of insulation films 202 stacked in multiple layers, first signal patterns 204s, 204c, and 204d, second signal patterns 212s, 212c, and 212d, package power layers 206, package ground layers 210, third signal patterns 208, and package substrate through vias 220s, 220c, and 220d. A dam 140 is formed on the package substrate 200. The first semiconductor chip 100 is mounted on the package substrate 200 such that the second signal patterns 212c and 212d are in contact with the first inner solder balls 19. A second underfill resin film 142 is formed to fill a space between and around the first inner solder balls 19. The dam 140 prevents liquid underfill resin for the second underfill resin film 142 from being spread into a prohibition region. Outer solder balls 230s, 230c, and 230d are attached to a lower part of the package substrate 200.

Returning to FIG. 1, a package adhesion pattern 310 is formed on an exposed package cap interconnection signal pattern 212s of the package substrate 200. The package adhesion pattern 310 may be formed by pasting or ink-jetting a conductive adhesive. A package cap 300 is covers the first and second semiconductor chips 100 and 120 and contacts the package adhesion pattern 310. The package cap 300 contacts the thermal interface film 132. The thermal interface film 132 can be formed previously during a process described in FIG. 11 or just before the package cap 300 is applied. Alternatively, the outer solder balls 230s, 230c, and 230d can be attached after the package cap 300 is applied. As a result, the semiconductor package 500 illustrated in FIG. 1 is manufactured.

In an exemplary embodiment, the package cap 300 prevents the package substrate 200 from being warped or twisted. The semiconductor package 500 has radiation and electromagnetic wave shield functions. This means that processes for electromagnetic wave shielding and radiation are not needed at a semiconductor module level or a mother board level. Accordingly, it is possible to simplify a following assembly process.

FIG. 14 is a cross-sectional view of a semiconductor package according to an embodiment of the inventive concept.

Referring to FIG. 14, a semiconductor package 501 according to an embodiment of the inventive concept includes package cap interconnection through vias 220s in contact with package ground layers 210. Further, a chip ground voltage through via 220c is in contact with a package ground layer 210. This means that the package cap 300 and first and second semiconductor chips 100 and 120 are supplied with a ground voltage V_{SS} through the same path. That is, the package cap 300 and first and second semiconductor chips 100 and 120 are grounded via the same path. As a result, it is possible to effectively reduce EMI. The semiconductor package 501 in FIG. 14 has the fabrication process and configuration similar to the embodiments described with reference to FIGS. 1-13 except for the above-described difference.

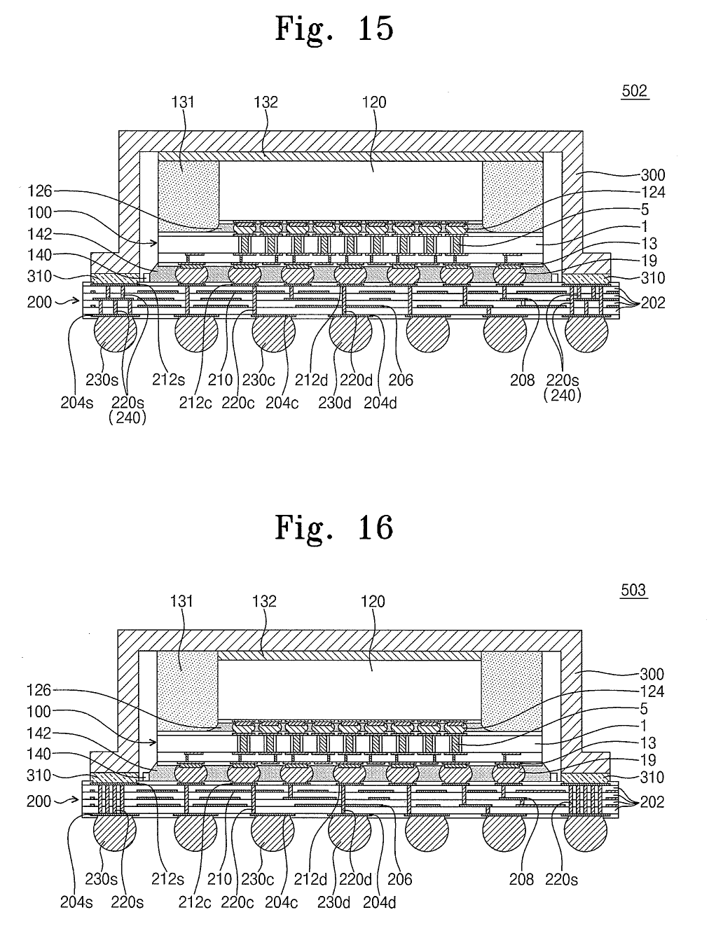

FIG. 15 is a cross-sectional view of a semiconductor package according to an embodiment of the inventive concept.

Referring to FIG. 15, a semiconductor package 502 according to an embodiment of the inventive concept includes package cap interconnection through vias 220s which are formed of a plurality of sub through vias 240. The sub through vias 240 do not overlap each other in a vertical direction. According to an embodiment, the sub-through vias 240 are disposed in an up-down zigzag configuration. The semiconductor package 502 in FIG. 15 has a fabrication process and configuration similar to the embodiments described in connection with FIGS. 1-13, except for the above-described difference.

FIG. 16 is a cross-sectional view of a semiconductor package according to an embodiment of the inventive concept.

Referring to FIG. 16, a semiconductor package 503 according to an embodiment of the inventive concept includes a molding film 131 whose upper surface is higher than that of a second semiconductor chip 120. The upper surface of the molding film 131 is placed at the same height as that of a thermal interface film 132. The upper surface of the molding film 131 contacts the package cap 300. The thermal interface film 132 is changed into a liquid state at a high temperature during a semiconductor package fabrication process. In this case, since the upper surface of the molding film 131 is higher in height than that of the second semiconductor chip 120, the molding film 131 contains the liquid-state thermal interface film 132. The semiconductor package 503 in FIG. 16 has a fabrication process and configuration similar to the embodiment described in connection with FIGS. 1-13, except for the above-described difference.

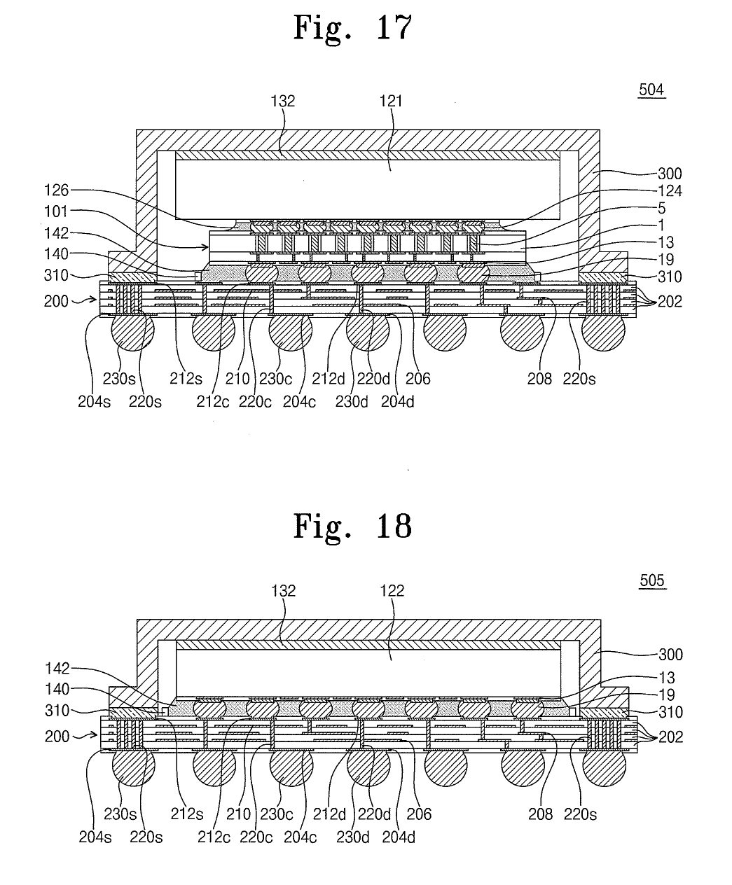

FIG. 17 is a cross-sectional view of a semiconductor package according to an embodiment of the inventive concept.

Referring to FIG. 17, a semiconductor package 504 according to an embodiment of the inventive concept includes first and second semiconductor chips 101 and 121. A width of the first semiconductor chip 101 is narrower than a width of the second semiconductor chip 121. The semiconductor package 504 does not include a molding film. The semiconductor package 504 in FIG. 17 has a fabrication process and configuration similar to the embodiments described in connection with FIGS. 1-13, except for the above-described difference.

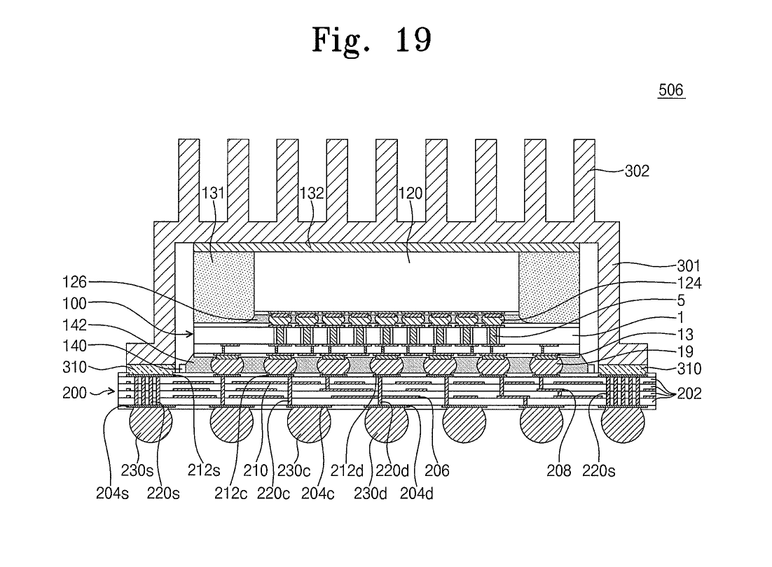

FIG. 18 is a cross-sectional view of a semiconductor package according to an embodiment of the inventive concept.

Referring to FIG. 18, a semiconductor package 505 according to an embodiment of the inventive concept includes one semiconductor chip 122 mounted on a package substrate 200, and does not include semiconductor chip 100. The semiconductor package 505 also does not include a molding film. The semiconductor package 505 in FIG. 18 has a fabrication process and configuration similar to the embodiments described in connection with FIGS. 1-13 except for the above-described difference.

FIG. 19 is a cross-sectional view of a semiconductor package according to an embodiment of the inventive concept.

Referring to FIG. 19, a semiconductor package 506 according to an embodiment of the inventive concept includes a plurality of pins 302 projecting from a package cap 301 in a direction away from the semiconductor package 506. This structure enables a heat radiation function to be increased. The semiconductor package 506 in FIG. 19 has a fabrication process and configuration similar to the embodiments described in connection with FIGS. 1-13 except for the above-described difference.

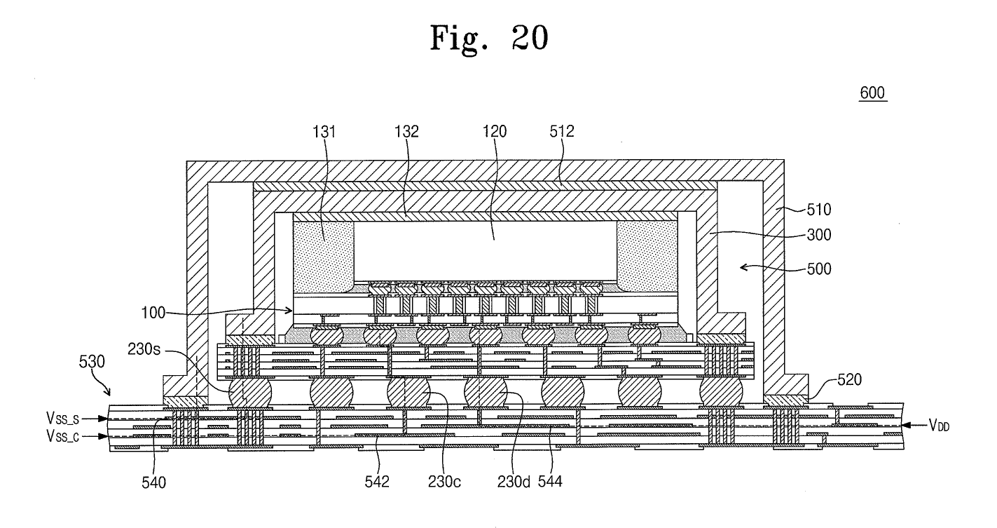

FIG. 20 is a cross-sectional view of a semiconductor package according to an embodiment of the inventive concept.

Referring to FIG. 20, a semiconductor package 600 according to an embodiment of the inventive concept includes a semiconductor package 500 of FIG. 1 mounted on a module substrate 530 and a module cap 510 covering the semiconductor package 500. The module cap 510 is adhered to the module substrate 530 by a module adhesion pattern 520 so as to be fixed. A module thermal interface film 512 is interposed between the module cap 510 and an upper surface of the semiconductor package 500 on the module cap 300.

According to an embodiment, the module substrate 530 is a multi-layer printed circuit board which includes a first module ground layer 540, a second module ground layer 542, and a module power layer 544 embedded therein. The first module ground layer 540 is electrically connected with a package cap 300 and is supplied with a cap ground voltage V_{SS}_{_{—}}_{S}. In an exemplary embodiment, the module cap 510 is electrically connected with the first module ground layer 540 and is supplied with a cap ground voltage V_{SS}_{_{—}}_{S}. The second module ground layer 542 is electrically connected with first and second semiconductor chips 100 and 120 and is supplied with a chip ground voltage V_{SS}_{_{—}}_{C}. The module power layer 544 is electrically connected with the first and second semiconductor chips 100 and 120 and is supplied with a power supply voltage V_{DD}.

In an exemplary embodiment, the module cap 510 and the package cap 300 share a common electrical connection to the first module ground layer 540. Alternatively, the module cap 510 and the package cap 300 are electrically connected with different layers independently. According to an embodiment, ground voltages are applied to the module cap 510 and the package cap 300 through different paths.

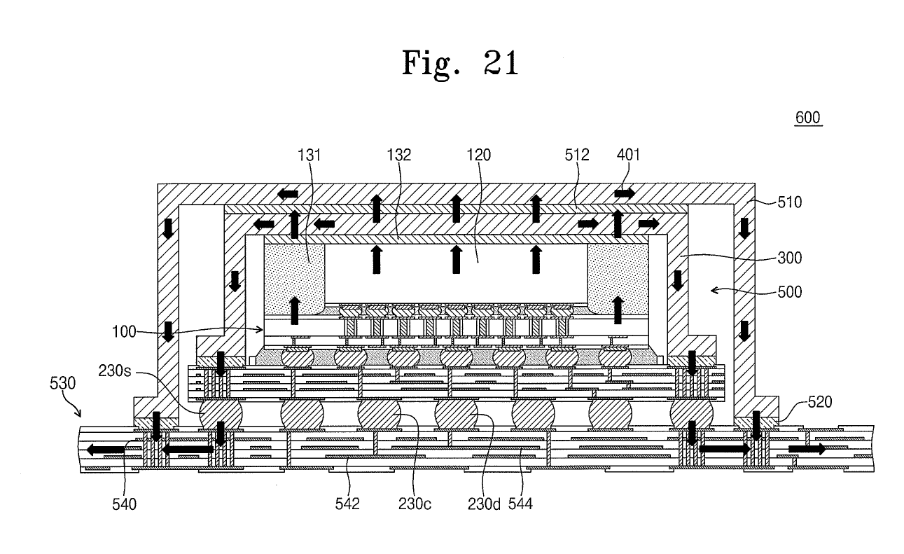

FIG. 21 is a diagram showing heat transmission in the semiconductor package of FIG. 20.

Referring to FIG. 21, heat produced by first and second semiconductor chips 100 and 120 is transmitted mainly along an arrow direction 401. The heat produced by the second semiconductor chip 120 is discharged to a module substrate 530 through a package thermal interface film 132 formed on the second semiconductor chip 120, a package cap 300, a module thermal interface film 512, and a module cap 510. The module cap 510 enables a heat radiation effect and an electromagnetic shield effect to be increased.

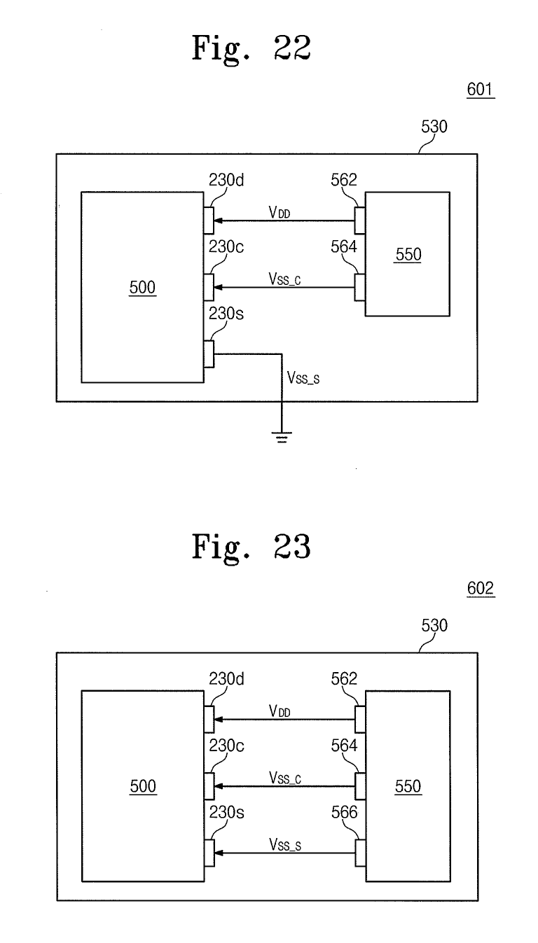

A semiconductor package according to an exemplary embodiment of the inventive concept can be applied to a semiconductor module. This is more fully described with reference to FIGS. 22 to 24.

FIG. 22 is a block diagram showing an embodiment of a semiconductor module including a semiconductor package according to an exemplary embodiment of the inventive concept.

Referring to FIG. 22, a semiconductor module 601 according to an embodiment of the inventive concept includes a semiconductor package 500 and a power management unit 550 which are mounted on a module substrate 530. The semiconductor package 500 includes a package cap interconnection solder ball 230s, a chip ground voltage solder ball 230c, and a power supply voltage solder ball 230d. In an exemplary embodiment, the package cap interconnection solder ball 230s is grounded without passing through the power management unit 550. A power supply voltage V_{DD} is supplied to the power supply voltage solder ball 230d through a first terminal 562 of the power management unit 550. A chip ground voltage V_{SS}_{_{—}}_{C} is supplied to the chip ground voltage solder ball 230c through a second terminal 564 of the power management unit 550.

The semiconductor package 500 may be identical to that illustrated in FIG. 1. The semiconductor module 601 may be applied to a wired electronic device, such as, for example, a television.

FIG. 23 is a block diagram showing an embodiment of a semiconductor module including a semiconductor package according to an exemplary embodiment of the inventive concept.

Referring to FIG. 23, a semiconductor module 602 according to an embodiment of the inventive concept includes a semiconductor package 500 and a power management unit 550 which are mounted on a module substrate 530. The semiconductor package 500 includes a package cap interconnection solder ball 230s, a chip ground voltage solder ball 230c, and a power supply voltage solder ball 230d. The power management unit 550 includes a first terminal 562, a second terminal 564, and a third terminal 566. In an exemplary embodiment, a power supply voltage V_{DD} is supplied to the power supply voltage solder ball 230d through the first terminal 562 of the power management unit 550. A chip ground voltage V_{SS}_{_{—}}_{C} is supplied to the chip ground voltage solder ball 230c through the second terminal 564 of the power management unit 550. A cap ground voltage VSS_S is applied to the package cap interconnection solder ball 230s through the third terminal 566 of the power management unit 550.

The semiconductor package 500 may be identical to that illustrated in FIG. 1. The semiconductor module 602 may be applied to a wired electronic device such as, for example, a television.

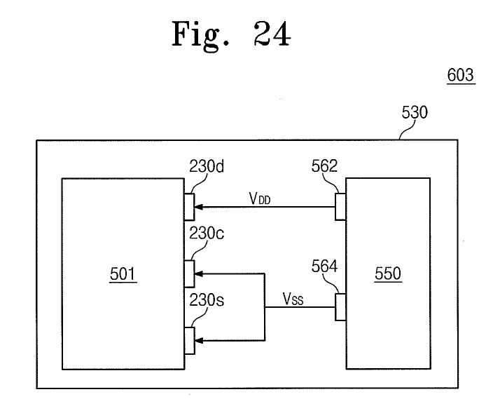

FIG. 24 is a block diagram showing an embodiment of a semiconductor module including a semiconductor package according to an exemplary embodiment of the inventive concept.

Referring to FIG. 24, a semiconductor module 603 according to an embodiment of the inventive concept includes a semiconductor package 501 and a power management unit 550 which are mounted on a module substrate 530. The semiconductor package 501 includes a package cap interconnection solder ball 230s, a chip ground voltage solder ball 230c, and a power supply voltage solder ball 230d. The power management unit 550 includes a first terminal 562 and a second terminal 564. In an exemplary embodiment, a power supply voltage VDD is applied to the power supply voltage solder ball 230d through the first terminal 562 of the power management unit 550. A ground voltage VSS is supplied to the package cap interconnection solder ball 230s and to the chip ground voltage solder ball 230c through the second terminal 564 of the power management unit 550.

The semiconductor package 501 may be identical to that illustrated in FIG. 14. The semiconductor module 603 may be applied to a wireless electronic device such as, for example, a cellular phone.

The above-describe package technology may be applied to an electronic device (or, an electronic system).

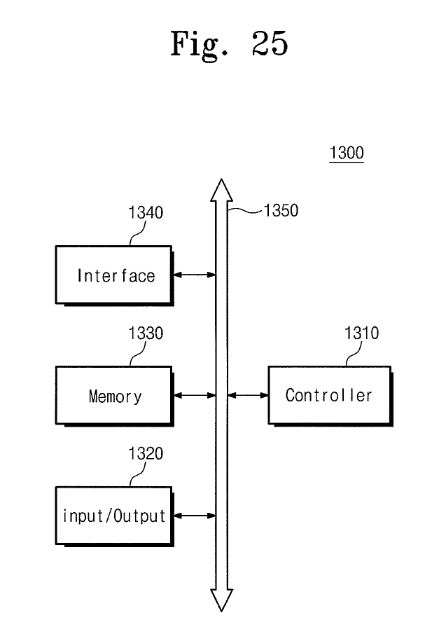

FIG. 25 is a block diagram showing an electronic device including a semiconductor package according to exemplary embodiments of the inventive concept.

Referring to FIG. 25, an electronic device 1300 includes a controller 1310, an input/output unit 1320, and a memory device 1330 which are interconnected via a bus 1350 as a data path. The controller 1310 may include any one of at least one microprocessor, digital signal processor, microcontroller, and logical elements capable of executing the same functions as the at least one microprocessor, the digital signal processor, and the microcontroller. The controller 1310 and the memory device 1330 include a semiconductor package according to an exemplary embodiment of the inventive concept. The input/output unit 1320 may include at least one of a keypad, a keyboard, a display device, and the like. The memory device 330 is a device for storing data. The memory device 1330 stores data and/or commands executed by the controller 1310. The memory device 1330 may include a volatile memory device and/or a non-volatile memory device. Alternatively, the memory device 1330 may include a flash memory. For example, an information processing system such as a mobile device or a desktop computer includes a flash memory to which the embodiments of the inventive concept are applied. The flash memory may be formed of a solid state disk device. In this case, the electronic device 1300 may stably store mass data in the flash memory.

According to an embodiment, the electronic device 1300 further includes an interface 1340 which is configured to transmit and/or receive data to or from a communication network. The interface 1340 may be formed to operate in wired and wireless manners. For example, the interface 1340 includes an antenna and/or a wired/wireless transceiver. Although not shown in FIG. 25, the electronic device 1300 may further include an application chipset, a camera image processor (CIS), and the like.

The electronic device 1300 may be implemented by a mobile system, a personal computer, an industrial personal computer, or a logic system executing various functions. For example, the mobile system may be a personal digital assistant, a portable computer, a web tablet, a mobile phone, a wireless phone, a laptop computer, a memory card, a digital music system, and/or an information sending/receiving system. In the event that the electronic device 1300 executes wireless communications, it may use a communication interface protocol which is applied to a 3G communication system such as CDMA, GSM, NADC, E-TDMA, WCDMA, and CDMA200, or other communication system.

A semiconductor package according to an exemplary embodiment of the inventive concept includes a package cap which is capable of radiating high temperatures and performs a shield function for preventing transmission of electromagnetic waves. This enables chip malfunctions to be prevented and the reliability of the devices to be improved. The package cap also prevents a package substrate from being warped or twisted. Due to the semiconductor package radiation and electromagnetic wave shield functions, processes for electromagnetic wave shielding and radiation are not needed at a semiconductor module level or a mother board level. Accordingly, it is possible to simplify a following assembly process.

A semiconductor package according to an exemplary embodiment includes a package cap which is fixed and connected to a package substrate by an adhesion pattern disposed on the package substrate. Accordingly, it is unnecessary to form holes for shield cans or thermal sink plates at a package substrate, a module substrate, or a mother board. As a result, it is unnecessary to alter the designs for package, module, or mother substrates to allow for heat radiation and shielding of electromagnetic waves.

In a semiconductor package according to another embodiment of the inventive concept, a width of a second semiconductor chip stacked on a first semiconductor chip is narrower than that of the first semiconductor chip, and the first and second semiconductor chips are covered by a package cap. A mold film is interposed between the first semiconductor chip and the package cap. As compared with the case that the mold film is not interposed between the first semiconductor chip and the package cap (e.g., only air is between the first semiconductor chip and the package cap), the mold film has a higher thermal conductivity than air, so that it is possible to more effectively radiate the heat produced by the lowermost semiconductor chip in a stacked semiconductor chip structure.

With a semiconductor package according to still another embodiment of the inventive concept, a thermal interface film is disposed between a second semiconductor chip and a package cap, and an upper surface of a molding film is higher than that of a second semiconductor chip. The thermal interface film is changed into a liquid state at a high temperature during a package making process. Since the upper surface of the molding film is higher than that of the second semiconductor chip, the molding film contains the thermal interface film in the liquid state.

With a semiconductor package according to still another embodiment of the inventive concept, a package substrate including embedded semiconductor chips may include a package cap interconnection through via and an embedded ground layer. The package cap interconnection through via is not connected with the ground layer. That is, the package cap may be grounded through a path different from that of the semiconductor chips. In this case, it is possible to reduce the ESD noise more effectively.

In some embodiments, the package cap interconnection through via is connected with the ground layer. That is, the package cap is grounded via the same path as the semiconductor chips. In this case, it is possible to reduce the EMI more effectively.

Although the present inventive concept has been described in connection with the embodiments of the present inventive concept illustrated in the accompanying drawings, it is not limited thereto. It will be apparent to those skilled in the art that various substitutions, modifications and changes may be made thereto without departing from the scope and spirit of the inventive concept.

1. A semiconductor package comprising:
a package substrate including a through via adjacent an edge of the package substrate;
a first semiconductor chip stacked on the package substrate;
at least one second semiconductor chip stacked on the first semiconductor chip and having a width narrower than a width of the first semiconductor chip;
a molding film covering a portion of an upper surface of the first semiconductor chip adjacent to a lateral surface of the second semiconductor chip, and covering the lateral surface of the second semiconductor chip;
a thermal interface film disposed on the second semiconductor chip;
a package cap in contact with the thermal interface film and covering the first and second semiconductor chips; and
a package adhesion pattern between the through via and a part of the package cap.

2. The semiconductor package of claim 1, wherein an upper surface of the molding film is positioned at the same height as an upper surface of the second semiconductor chip and the thermal interface film is positioned between the molding film and the package cap.

3. The semiconductor package of claim 1, wherein an upper surface of the molding film is higher than an upper surface of the second semiconductor chip.

4. The semiconductor package of claim 1, wherein the package substrate further comprises a ground layer, the through via being in contact with the ground layer.

5. The semiconductor package of claim 1, wherein the package substrate further comprises a ground layer, the through via being out of contact with the ground layer.

6. The semiconductor package of claim 1, wherein the through via includes a conductive film.

7. The semiconductor package of claim 1, wherein the through via includes an insulation film.

8. The semiconductor package of claim 1, wherein the package adhesion pattern is conductive.

9. The semiconductor package of claim 1, wherein the package cap includes a portion protruding from the package cap.

10. The semiconductor package of claim 1, wherein the package substrate further comprises conductive layers and a plurality of insulation films stacked in a multi-layer structure, and the through via includes a plurality of sub through vias in the insulation films and disposed at different layers from each other, and wherein adjacent sub through vias in a vertical direction are offset from each other.

11. The semiconductor package of claim 1, wherein the package substrate further comprises a power layer, and the through via is not connected with the power layer.

12. The semiconductor package of claim 1, wherein the molding film includes thermal epoxy.

13. The semiconductor package of claim 1, wherein the thermal interface film includes thermal grease, an epoxy material, or metallic solid particles included in an epoxy material.

14. A semiconductor module comprising;
a module substrate; and
a semiconductor package mounted on the module substrate,
wherein the semiconductor package comprises:
a package substrate including a through via adjacent an edge of the package substrate;
a first semiconductor chip stacked on the package substrate;
at least one second semiconductor chip stacked on the first semiconductor chip and having a width narrower than a width of the first semiconductor chip;
a molding film covering a part of an upper surface of the first semiconductor chip adjacent to a lateral surface of the second semiconductor chip, and covering the lateral surface of the second semiconductor chip;
a thermal interface film disposed on the second semiconductor chip;
a package cap contact with the thermal interface film and covering the first and second semiconductor chips; and
a package adhesion pattern between the through via and a part of the package cap.

15. The semiconductor module of claim 14, further comprising:
a module cap covering the semiconductor package and positioned on the module substrate; and
a module adhesion pattern between the module cap and the module substrate.

16. The semiconductor module of claim 14, further comprising:
a power management unit mounted on the module substrate and supplying a cap ground voltage to the package cap and a chip ground voltage to one of the first and second semiconductor chips.

17. The semiconductor module of claim 14, further comprising:
a power management unit mounted on the module substrate and supplying a chip ground voltage to one of the first and second semiconductor chips, the package cap having a connection to ground that does not pass through the power management unit.

18. An electronic device comprising:
a semiconductor module including a module substrate and a semiconductor package mounted on the module substrate; and
an input/output unit receiving and transmitting signals from and to the semiconductor module,
wherein the semiconductor package comprises:
a package substrate including a through via adjacent an edge of the package substrate;
a first semiconductor chip stacked on the package substrate;
at least one second semiconductor chip stacked on the first semiconductor chip and having a width narrower than a width of the first semiconductor chip;
a molding film covering a part of an upper surface of the first semiconductor chip adjacent to a lateral surface of the second semiconductor chip, and covering a lateral surface of the second semiconductor chip;
a thermal interface film disposed on the second semiconductor chip;
a package cap in contact with the thermal interface film and covering the first and second semiconductor chips; and
a package adhesion pattern between the through via and a part of the package cap.

19-20. (canceled)

21. A semiconductor package comprising:
a package substrate including a through via;
a first semiconductor chip stacked on the package substrate;
at least one second semiconductor chip stacked on the first semiconductor chip and having a width narrower than a width of the first semiconductor chip;
a molding film on a portion of an upper surface of the first semiconductor chip adjacent to a lateral surface of the second semiconductor chip;
a thermal interface film disposed on the second semiconductor chip;
a package cap in contact with the thermal interface film and positioned over the first and second semiconductor chips; and
a conductive package adhesion pattern between the through via and a part of the package cap.
